(19) United States
(12) Patent Application Publication
(10) Pub. No.: US 2002/0182876 A1
(43) Pub. Date: Dec. 5, 2002

(54) Semiconductor device fabrication method and apparatus

(75) Inventor: Kenji Kawai, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/131,242

(22) Filed: Apr. 25, 2002

(30) Foreign Application Priority Data
Jun. 1, 2001 (JP) 2001-166681(P)

(51) Int. Cl. H01L 21/461

(52) U.S. Cl. 438/706

(57) ABSTRACT

A semiconductor device etching method and apparatus can be used to etch a silicon insulation film and an underlying film with a high etch selectivity free of a significant variation. The apparatus uses a fluorocarbon type gas as an etching gas to etch a thin film of a semiconductor device placed in a reaction chamber thereof and it includes an etching-gas introduction means introducing the etching gas into the reaction chamber, the reaction chamber in which an etching step is effected, an exhaust means exhausting a gas from the reaction chamber, wherein a substance preventing a polymerization reaction of a fluorocarbon type molecule covers a surface of a portion of the reaction chamber contacting the etching gas.

### BACKGROUND OF THE INVENTION

1. Field of the Invention

The present invention relates generally to semiconductor fabrication methods and apparatuses and particularly to semiconductor fabrication methods and apparatuses preventing a polymer film from adhering to an internal wall of a chamber and thus producing particles in etching a thin film of a semiconductor device.

2. Description of the Background Art

FIG. 7 shows a conventional plasma etching apparatus allowing top and bottom electrodes 107 and 108 and a coil 106 around a reaction chamber 102 to receive radio frequency (RF) power from RF power supplies 103, 104, 105, respectively. The RF power of top electrode 107 and coil 106 can control a plasma density for example of an etchant and that of the lower electrode can control ion energy of the etchant, independently. An etching gas is introduced into reaction chamber 102 via a gas inlet 109.

Since a compound having a cyclic bond of C—C is prone to polymerization reaction when the ring is opened, if, with silicon underlying, a silicon oxide (SiO₂) film thereon is selectively etched, a fluorocarbon type gas having a cyclic bond for example of C₄F₈ or C₅F₈ is used frequently. When a polymerization reaction of an etching gas occurs, polymer deposits on the underlying silicon to protect it against the etching. This can provide a high etch selectivity of a thin film to be etched to the underlying film. A chemical compound having an unsaturated bond, i.e., a double bond, a triple bond between carbon atoms is also prone to polymer polymerization and it is also used to selectively etch a silicon oxide film on silicon.

If hexafluorobutadiene C₄F₆ having an unsaturated bond, CH₂F₂ and O₂ are used in the form of a gaseous mixture and the mixture simply causes polymerization reaction a reaction involved therein can be represented by:

CF₂═CF—CF═CF₂+CF₂═CF—CF—CF₂+→(CF₂—CF═CF—CF₂—CF₂—CF═CF—CF₂)n (1)

Furthermore, if octafluorocyclobutane C₄F₈, CH₂F₂ and O₂ in the form of a gaseous mixture simply cause polymerization reaction, a polymer —CF₂—CF₂—CF₂—CF₂— is produced.

An apparatus used to etch a thin film of a semiconductor device is enhanced in maintainability by arranging on an internal wall 120 of the reaction chamber a deposition shield cover 104 coated for example with aluminum or alumite treated aluminum or highly plasma resistant MgO or Y₂O₃ (yttria). Whenever the chamber is cleaned, the deposition shield cover is exchanged to protect the internal wall from damage. Furthermore, exchanging a used deposition shield cover with a new deposition shield cover can reduce production of particles and the like and thus increase the production yield of the semiconductor device.

On the deposition shield cover or on internal wall 120 of the chamber if the deposition shield cover does not exist, however, a fluorocarbon type polymer deposits for a short period of time before the deposition shield cover is exchanged. If a polymer of a fluorocarbon type molecule deposited would then come off and particles (foreign matters) are thus introduced and mixed into a semiconductor substrate 113 and the device yield is significantly reduced. More specifically, if deposition shield cover 114 is periodically exchanged, particles are still inevitably introduced before the cover is exchanged with another cover. Furthermore, frequently exchanging deposition shield covers results in the etching apparatus operating less efficiently and hence the device being produced less efficiently.

Such introduction of particles can be prevented by heating the reaction chamber's wall to a high temperature to prevent the polymer from adhering thereto, although there is a limitation on increasing the temperature of the wall of the reaction chamber, otherwise the apparatus would not operate reliably or safely.

### SUMMARY OF THE INVENTION

The present invention contemplates a semiconductor device fabrication method and apparatus which does not require a reaction chamber having a wall heated to high temperature to etch a thin film to be etched, a silicon insulation film in particular, and an underlying film with a high etch selectivity and also prevents a polymer from adhering to an internal surface of the reaction chamber and thus introducing particles.

The present invention provides a semiconductor device fabrication apparatus using a fluorocarbon type gas as an etching gas to etch a thin film of a semiconductor device in a reaction chamber thereof, including: an etching gas introduction means introducing an etching gas into a reaction chamber; a reaction chamber in which a thin film of the semiconductor device is etched; and an exhaust means exhausting a gas from the reaction chamber, a substance preventing a polymerization reaction of a molecule of the fluorocarbon type gas being provided internal to the reaction chamber to cover a surface of a portion of the reaction chamber contacting the etching gas.

Thus in providing an etching step using a fluorocarbon type gas as an etching gas an underlying film can have a surface with a fluorocarbon type polymer film depositing thereon while the etching apparatus can have a predetermined portion without the fluorocarbon type polymer film adhering thereto. This can improve an etch selectivity of an insulation film to be etched to the underlying film and also prevent the fluorocarbon type polymer film from adhering for example to an internal surface of the reaction chamber thick. Thus, the device can be etched with a high dimensional precision and the device being fabricated can be free from dust of the fluorocarbon type polymer film otherwise produced and particles of the film thus mixed with the device and thus reducing the yield of the devices.

While the anti-polymerization reaction substance may cover the entirety of the internal surface of the reaction chamber that contacts the etching gas, it is also effective if the substance only partially covers the surface of a predetermined portion of the reaction chamber. For example, it is also effective if the substance simply covers the reaction chamber's ceiling, upper sidewall and other similar portions at which particles are readily produced and mixed into the semiconductor substrate.

Furthermore, the anti-polymerization reaction substance may be provided through vapor deposition, sputtering, laser abrasion or any other similar, predetermined technique employed to form a thin film, or if is metal, metal foil or the like may be fixed on the surface.

The etching-gas introduction means can introduce not only the fluorocarbon type gas but also other gas for mixture. The etching-gas introduction means can include not only a gas feed path but also a cylinder of the fluorocarbon type gas and a cylinder of a different type of gas. Furthermore, the present semiconductor fabrication apparatus can include a plasma etching apparatus, a parallel plate reactive ion etching apparatus, an electron cyclotron resonance (ECR) apparatus, a downstream plasma reaction apparatus and the like. The thin film to be etched includes silicon oxide film, silicon nitride film, silicon oxynitride film, polysilicon film and the like. A type of metal film, such as aluminum film, is not etched in the present invention.

In the present apparatus the reaction chamber can have an internal surface covered with a deposition shield cover and the anti-polymerization reaction substance preventing the polymerization reaction can cover a surface of the deposition shield cover.

If the polymerization reaction of the fluorocarbon molecule cannot be prevented completely, polymer film gradually adheres to an internal wall of the reaction chamber. Furthermore, a substance other than fluorocarbon type polymer that produces dust can also adhere to an internal surface of the reaction chamber. The deposition shield cover can be exchanged periodically, for example whenever the chamber is cleaned, before the polymer film becomes too thick and thus comes off. Thus the configuration as described above can more reliably reduce the possibility of introduction of particles.

In the present apparatus the substance preventing the polymerization reaction can cover a surface of a substrate support supporting a substrate of the semiconductor device.

If the substrate support has a surface covered with the deposition shield cover or the substrate support is covered with the deposition shield cover, the cover can have a surface with the substance arranged thereon to reduce the polymerization reaction.

In the present apparatus the substance preventing the polymerization reaction can cover an internal surface of a piping of a pump of the exhaust means.

Thus the piping of the pump can be free of fluorocarbon type polymer film adhering thereto and clogging the same and the pump can be free from failure attributed to the polymer film. Note that the piping of the pump includes an interior of the pump device, and a piping preceding and following the pump, and any other similar portion in contact with the fluorocarbon type gas. Furthermore, the substance preventing the polymerization reaction may entirely cover the internal surface of the piping of the pump, although it is sufficiently effective if the substance only partially covers the internal surface of the piping of the pump.

In the present apparatus the substance preventing the polymerization reaction can further cover a surface of a gas passageway of a reaction tower internal to a hazard eliminating device provided in the exhaust means.

Thus, on a surface of the substance of the reaction tower, fluorocarbon can be converted to have a lower molecule weight. If the substance contains an oxidization catalyst, desirably a gas supplying the conversion reaction with an oxygen atom such as gaseous oxygen, is supplied to the reaction tower. If the substance contains a catalyst for hydrogenation, desirably a gas supplying the conversion reaction with a hydrogen atom such as gaseous hydrogen, is introduced into the reaction tower.

Thus, fluorocarbon type gas can be decomposed at a lower temperature, more readily, at a lower cost and with a lower power than when a conventional, hazardous perfluorocarbon eliminating device is used.

In the present apparatus, a substrate containing the substance preventing the polymerization reaction can be arranged in the reaction chamber and etched to adhere the substance to an internal surface of the reaction chamber.

Thus a conventional etching apparatus can have a reaction chamber having an internal surface with the substance readily adhering thereto to prevent fluorocarbon type polymer film from adhering thereto. In this case, the substance scatters from the substrate with distribution characteristics unit to the etching apparatus of interest and adheres to and thus covers each portion internal to the reaction chamber.

In the present apparatus, the substance preventing the polymerization reaction can be a catalyst for hydrogenation.

Thus, a catalyst for hydrogenation can be arranged in the etching apparatus at a predetermined position, a hydrogen atom can be supplied from a gas capable of supplying it, and polymerization of fluorocarbon type gas can be prevented by forming an H terminal. As such, any particular substance is not required and instead a typical catalyst for hydrogenation can be used to prevent polymerization reaction of the fluorocarbon type gas at the location of the catalyst for hydrogenation. Note that if a catalyst for hydrogenation is used, desirably a gas supplying a hydrogen atom contributing to the reaction forming the H terminal, is used in the form of a mixture with the fluorocarbon type gas.

In general, a catalyst only reduces activation energy of a chemical reaction and its amount does not vary between before and after the reaction. As such, the catalyst of a small amount can be arranged to continue the H terminal formation or any other target reaction. The catalyst also reduces activation energy of the opposite reaction and if continuing the reaction of interest is desired a reaction product produced in response to the reaction needs to be removed in response to the reaction. This can be achieved by exhausting the product by means for example of an exhaust pump.

In the present apparatus, the catalyst for hydrogenation can be at least one of palladium (Pd), platinum (Pt), platinum/platinum oxide (Pt/PtO) and rhenium sulfide (ReS₂).

These catalysts for hydrogenation are commercially available and thus readily obtained, and arranged by sputtering, vapor deposition and the like, readily in the form for example of coating on an internal surface of the reaction chamber.

In the present apparatus the substance preventing the polymerization reaction can be an oxidization catalyst.

An oxidization catalyst can receive an oxidization atom and allows the oxidization atom to cut or selectively oxidize an unsaturated bond, a cyclic bond or the like of the fluorocarbon type gas or a bond of a benzene ring to convert the fluorocarbon type gas to have a lower molecule weight. As such, at the location of the oxidization catalyst the polymerization reaction of course does not proceed nor does fluorocarbon type polymer adhere to the etching apparatus at a predetermined portion thick. Note that if an oxidization catalyst is used, desirably a gas supplying an oxygen atom contributing to the conversion, is used in a mixture with the fluorocarbon type gas. As has been described previously, a molecule having a lower molecular weight is exhausted for example by the exhaust pump and the reaction proceeds continuously to provide a lower molecular weight.

In the present apparatus the oxidization catalyst is formed of at least one of platinum/rhodium (Pt/Rh), vanadium pentoxide (V₂O₅), copper/vanadium (Cu/V), ruthenium oxide (RuOₓ) and osmium oxide (OsO_{y}).

These oxidization catalysts are commercially available and can readily be obtained and these substances can readily be arranged by sputtering, vapor deposition and the like to form a thin film arranged in the etching apparatus at a predetermined position.

In the present apparatus the anti-polymerization reaction substance can be a hydrogen storing or discharging metal. For example it can be formed of at least one of platinum (Pt) and palladium (Pd).

These metals are hydrogen storing metals as well as catalysts for hydrogenation and can thus store hydrogen in an appropriate step and supply a hydrogen atom contributing to a reaction forming an H terminal. This can in some case eliminate the necessity of using a gas capable of supplying a hydrogen atom in a mixture with fluorocarbon type gas.

In the present apparatus the fluorocarbon type gas can contain at least one of alkene (olefin) type gas, alkyne type gas, cycloalkane (cycloparaffin) type gas, cycloalkene (cylcoolefin) type gas and benzene derivative fluoride compound gas.

These fluorocarbon type gases are available in the industrial scale at a high level of purity inexpensively. Thus the etch selectivity of an insulating film to be etched and an underlying film can be increased and the insulation film can thus be etched with high precision.

Alkene (olefin) type gas can for example be hexafluorobutadiene (C₄F₆).

Cycloalkane (cycloparaffin) gas can for example be octafluorocyclobutane (C₄F₈).

Cycloalkene (cycloolefin) gas can for example be octafluorocyclopentene (C₅F₈).

The present apparatus can be a plasma etching apparatus.

Plasma does not cause highly directive energy flow and the apparatus can thus etch a subject highly efficiently without significantly affecting other portions. This further enhances for example in etching an insulation film the usefulness of using fluorocarbon type gas serving as an etching gas allowing a high etch selectivity of a film to be etched and the insulation film. The present etching apparatus can prevent dust, a detriment of the fluorocarbon type gas. Thus the present apparatus in the form of the above etching apparatus can significantly enhance the usefulness of the present invention.

The present invention provides a semiconductor device fabrication method using a fluorocarbon type gas as an etching gas to etch a thin film of a semiconductor device placed in a reaction chamber of an etching apparatus, including the steps of: etching in the reaction chamber a substrate having arranged therewith a substance preventing a polymerization reaction of a molecule of the fluorocarbon type gas; and introducing at least the fluorocarbon type gas into the reaction chamber and using the fluorocarbon type gas to etch a thin film of the semiconductor device.

Thus it is not necessary to arrange the anti-polymerization reaction substance on the internal surface of the reaction chamber to prevent the polymerization reaction, in particular as early as when the fabrication of the etching apparatus starts. More specifically, a conventionally used etching apparatus can have its reaction chamber having an internal surface with the anti-polymerization reaction substance applied thereto for example simply by etching a substrate having the anti-polymerization reaction substance sputtered thereon to form a surface layer thereof. The anti-polymerization reaction substance can be the aforementioned catalyst for hydrogenation, oxidization catalyst, and hydrogen storing/discharging substance. Note that the substrate is required to have a surface provided with an anti-polymerization reaction substance previously by sputtering, vapor-deposition, and the like.

Thus, a thin film to be etched can be etched efficiently with high precision and furthermore the reaction chamber can have an internal surface free of fluorocarbon type polymer contributing to production of dust.

In the present method, together with the fluorocarbon type gas a gas supplying a hydrogen atom or an oxygen atom contributing to at least one of a reaction allowing a fluorocarbon type molecule to have a lower molecule weight, an H termination reaction and an oxidization reaction, is introduced into the reaction chamber to etch the thin film of the semiconductor device.

Thus, if hydrogen gas is introduced, an H terminal preventing a polymerization reaction of fluorocarbon type gas can be formed for a fluorocarbon gas molecule. The hydrogen above and the hydrogen of the fluorocarbon type gas may be mixed at a ratio adjusted for example by mixing a third gas together. Furthermore, if oxygen gas is introduced, an oxygen atom is allowed to cut and oxidize an unsaturated bond of the fluorocarbon type gas molecule, a cyclic bond thereof, and the like to prevent polymerization of the fluorocarbon type gas molecule. This can in turn prevent production of a polymer of the fluorocarbon type gas molecule and hence a cause of dust to achieve a high yield of the semiconductor devices. Oxygen and the fluorocarbon type gas may be provided at a ratio adjusted by mixing a third gas and gaseous oxygen and fluorocarbon type gas together.

The present method uses any of the above-described apparatus to etch a thin film of a semiconductor device, including the steps of: setting in a reaction chamber of the apparatus a semiconductor substrate having a thin film formed thereon; and using at least a fluorocarbon type gas as an etching gas to etch the thin film of the semiconductor substrate placed in the reaction chamber.

Thus the thin film of the semiconductor device and an underlying film can be etched with a high etch selectivity and the reaction chamber can also have an internal surface free of fluorocarbon type polymer contributing to generation of dust. Thus a semiconductor device with high dimensional precision and of high yield can be fabricated.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 schematically shows a configuration of an apparatus in a first embodiment of the present invention for use in plasma-etching a semiconductor device;

FIG. 2 represents a chemical expression representing a reaction of an oxygen atom and a fluorocarbon type gas molecule in a second embodiment of the present invention in the presence of an oxidization catalyst Pt/Rh;

FIG. 3 represents a chemical expression representing a reaction of an oxygen atom and a fluorocarbon type gas molecule in a second embodiment of the present invention in the presence of an oxidization catalyst RuOx;

FIG. 4 illustrates a technique in a third embodiment of the present invention to etch a substrate containing an anti-polymerization reaction substance to adhering the substance to an internal surface of a reaction chamber;

FIG. 5 shows a plasma etching apparatus in a fourth embodiment of the present invention with an anti-polymerization reaction substance covering an internal surface of a reaction chamber and a piping of a pump system;

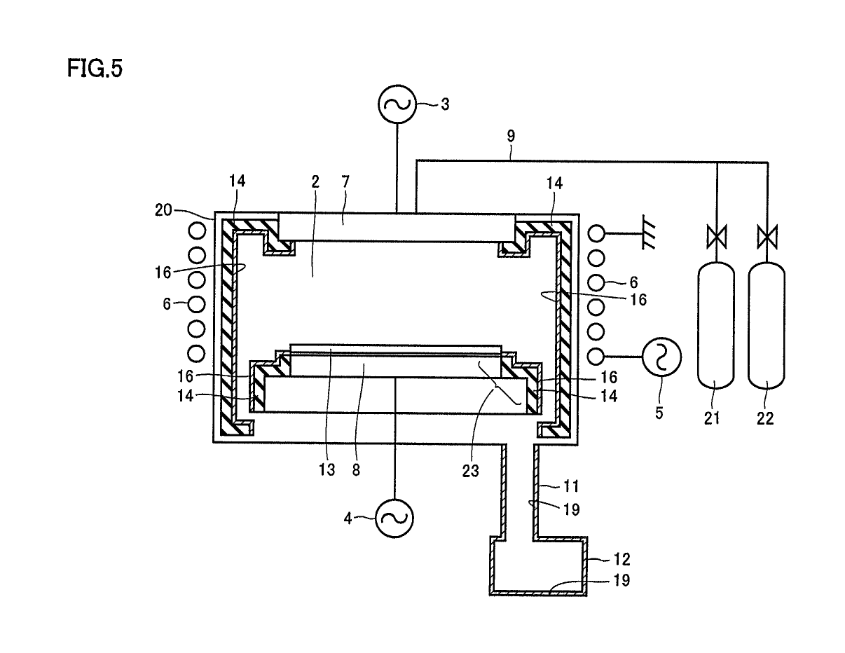

FIG. 6 shows a plasma etching apparatus in a fifth embodiment of the present invention with an anti-polymerization reaction substance arranged at a reaction tower removing hazardous perfluorocarbon (PFC); and

FIG. 7 shows a conventional plasma etching apparatus.

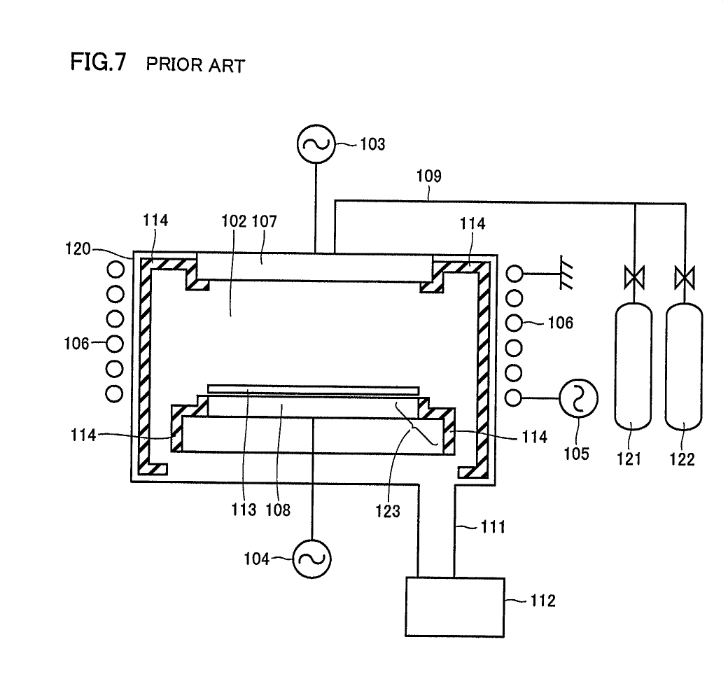

### DESCRIPTION OF THE PREFERRED EMBODIMENTS

With reference to the drawings the embodiments of the present invention will now be described.

First Embodiment

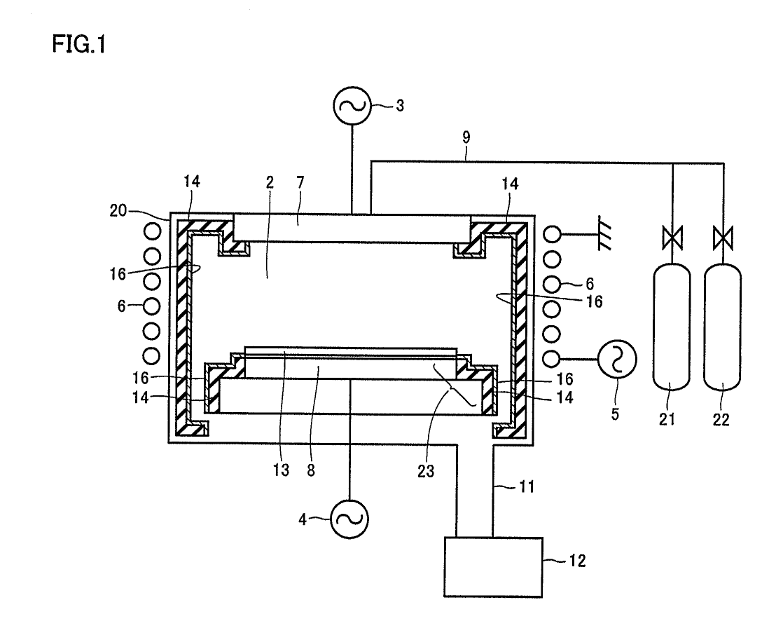

FIG. 1 shows a plasma etching apparatus including a reaction chamber having an internal wall 20 or a deposition shield cover 14 having adhering thereto a catalyst for hydrogenation formed of a substance reducing a polymerization reaction of fluorocarbon type gas, or having a surface containing such substances. Such a catalyst for hydrogenation can for example be palladium (Pd), platinum (Pt), platinum/platinum oxide (Pt/PtO), rhenium sulfide (ReS₂). Furthermore, as a metal storing or discharging hydrogen, platinum (Pt) or palladium (Pd) can be used.

In this plasma etching apparatus, top end bottom electrodes 7 and 8 and a coil 6 provided around a reaction chamber 2 receive radio-frequency (RF) power from RF power supplies 3, 4, 5, respectively. The RF power of top electrode 7 and that of coil 6 can control a plasma density for example of an etchant and that of the bottom electrode can control ion energy of the etchant, independently. Between a semiconductor substrate 13 and bottom electrode 8 and around the bottom electrode is arranged a substrate support 23 supporting the semiconductor substrate.

An etching gas is introduced into a reaction chamber 2 through a gas inlet 9. The gas inlet communicates with a cylinder of fluorocarbon type gas 21 and another cylinder 22 of other gas for mixture. Further more gas cylinders may be arranged to introduce a mixture of further more kinds of gas into the reaction chamber, and it is often the case to do so.

To start a discharge, an RF power lower than a power set for etching is applied to bottom electrode 8 to facilitate ignition of plasma. Then an RF power is applied to top electrode 7 or coil 6 and an RF power set for the etching is subsequently applied to bottom electrode 8. RF power is thus introduced stepwise because if the top electrode initially receives RF power a fluorocarbon polymer polymerized with an etchant would disadvantageously deposit on an object to be etched. It is disadvantageous that a fluorocarbon type polymer deposits from the beginning of the etching, whereas the polymer depositing on an underlying film during the etching is desirable as such can enhance the etch selectivity of the object to be etched over the underlying film.

Normally in etching for example a silicon oxide film (not shown) on semiconductor substrate 13 the etching rate of an underlying silicon or a resist mask is negligibly reduced and the silicon oxide film or a silicon nitride film is etched selectively. To implement such a selective etching step, a fluorocarbon type gas having a high atomic ratio of fluoride and carbon (a high (fluorine/carbon) or (F/C) ratio) is used as etchant. Generally, a fluorocarbon type gas having a F/C ratio of around 2 is optimal as it allows a fluorocarbon type polymer film to efficiently deposit on the underlying silicon and thus enhances the etch selectivity of the silicon oxide film and the like and the underlying film. For example, C₅F₈ approximately has optimal F/C ratio above-mentioned and suitable for the purpose.

Since a compound having a cyclic bond of C—C is prone to polymer polymerization when the ring is opened, if, with silicon underlying, a silicon oxide (SiO₂) film thereon is selectively etched, a fluorocarbon type gas having a cyclic bond for example of C₄F₈ or C₅F₈ is used. A chemical compound having an unsaturated bond, i.e., a double bond, a triple bond between carbon atoms is also prone to polymer polymerization and it is also used to selectively etch a silicon oxide (SiO₂) film on silicon.

The aforementioned fluorocarbon type gas includes a large number of types of gas and it can be at least one of alkene (olefin) type gas, alkyne type gas, cycloalkane (cycloparaffin) gas, cycloalkene, (cycloolefin) gas, or benzene derivative fluoride compound gas.

The etching step is provided using a gaseous mixture containing at least one type of the aforementioned fluorocarbon type gas and also at least one of CH₂F₂, CHF₃, CH₃F, NH₃, CH₄, H₂ and O₂, CO, CO₂, H₂O, H₂O₂, N₂O and Ar, He and Xe.

Specific examples of the fluorocarbon type gas are as follows:

alkene (olefin) type gas: hexafluorobutadiene (C₄F₆), hexafluoropropene (C₃F₆)

alkyne type gas: difluoroacethylene (C₂F₂), tetrafluoropropyne (C₃F₄)

cycloalkane (cycloparaffin) gas: octafluorocyclobutane (C₄F₈), perfluorocyclopentane or decafluorocyclopentane (C₅F₁₀)

perfluorocyclohexane or dodecafluorocyclohexane (C₆F₁₂)

cycloalkene (cycloolefin) gas: octafluorocyclopentene (C₅F₈), hexafluorocyclobutene (C₄F₆), perfluorohexene or decafluorohexene (C₆F₁₀)

benzen derivative fluoride compound: hexafluorobenzene (C₆F₆), octafluoronaphthalene (C₁₀F₈).

If the etching gas is a gaseous mixture of hexafluorobutadiene (C₄F₆), CH₂F₂ and O₂ by way of example the aforementioned catalyst for hydrogenation does not exist and if polymerization reaction is simply caused a polymer film is formed according to the following reaction:

CF₂═CF—CF═CF₂+CF₂═CF—CF—CF₂+→(CF₂—CF═CF—CF₂—CF₂CF═CF—CF₂)n (1)

As a substance preventing this polymerization reaction, a catalyst for hydrogenation such as platinum (Pt) is used. Pt is arranged for example through vapor deposition in the form of a thin film of Pt 16 on a surface of deposition shield cover 14 arranged to cover an internal wall 20 of the reaction chamber, substrate support 23 and the like. If herein a gas capable of supplying a hydrogen atom, such as CH₂F₂ has been introduced, a Pt containing portion has a surface having the following reaction:

(reaction in the presence of Pt catalyst): CF₂═CF—CF═CF₂+(H)→CHF₂CHFCHFCHF₂ (2)

to form an H terminal.

As a result of the above reaction, polymerization reaction does not proceed, and generation and hence adhesion of polymer is thus prevented. A hydrogen-storing alloy such as palladium (Pd) also allows a reaction forming the above H terminal.

Other than CH₂F₂, the gas capable of supplying a hydrogen atom can be CHF₃, CH₃F, H₂, H₂O, H₂O₂, NH₃, CH₄, CH₃OH (methanol), CH₃CH₂OH (ethanol), CH₃CH (CH₃)OH (isopropyl alcohol).

The aforementioned Pt, Pd and other similar catalysts for hydrogenation adhere to deposition shield cover 14 covering internal wall 20 of the reaction chamber and substrate support 23. In general, the aforementioned catalyst for hydrogenation reduces activation energy of a reaction such as formation of an H terminal and only serves to facilitate the above reaction. As such, the catalyst does not react to be a compound different from the original nor is it exhausted and the catalyst that exists in a small amount on a surface of the portion as described above can have a significant effect. It should be noted, however, that this catalyst also reduce activation energy of the opposite reaction and if a reaction product exists as it is produced on the catalyst, apparently the aforementioned H terminal formation reaction does not occur. In the above embodiment, an exhaust pump or the like is used to exhaust the reaction product and the H terminal formation reaction continues. This also applies to an embodiment described hereinafter.

The fluorocarbon type gas and a gaseous mixture thereof used in the etching step are exhausted by exhaust pump 12 via a vent 11.

While in the present embodiment the etching apparatus is a plasma etching apparatus, it may be a parallel plate reactive ion etching apparatus, an electron cyclotron resonance apparatus, a downstream plasma reaction apparatus, and the like.

As has been described previously, on a surface of a catalyst for hydrogen there occurs the aforementioned hydrogen reaction at an unsaturated bond of the fluorocarbon type gas and an H terminal is thus formed. As such, a polymer of the flourocarbon type gas is not produced and as a result the reaction chamber can have its internal wall free of such a polymer adhering thereto thick and particles otherwise generated and thus introduced into the semiconductor device.

Using Pt, Pd, i.e., metals storing and discharging hydrogen, are also similarly effective.

Second Embodiment

In a second embodiment of the present invention a plasma etching apparatus includes a reaction chamber having an internal wall or a deposition shield cover with an oxidization catalyst of a substance arranged to reduce polymerization reaction of the fluorocarbon type gas. The oxidization catalyst can for example be Pt/Rh, V₂O₅, Cu/V, Zn, RuOₓ.

If the etching gas is for example be C₄F₆ (hexafluorobutadiene) and CH₂F₂ and O₂ in the form of a gaseous mixture and polymerization reaction is simply caused, a polymer film forms, as represented by the following equation:

CF₂═CF—CF═CF₂+CF₂═CF—CF═CF₂+→(CF₂—CF═CF—CF₂CF₂CF═CF—CF₂)n (1).

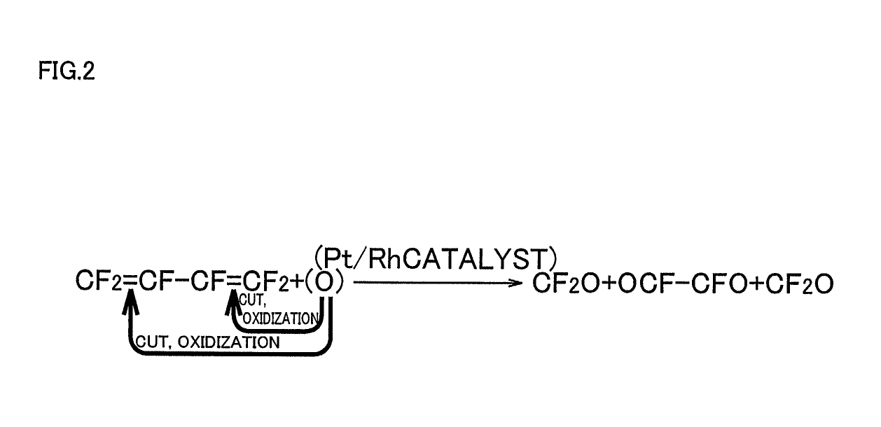

Herein, if a gas capable of supplying an oxygen atom, such as O₂ exists and a catalyst for example of Pt/Rh is used, an oxygen atom attacks an unsaturated bond of hexafluorobutadiene, as shown in FIG. 2. Consequently, hexafluorobutadiene has the unsaturated bond cut and oxidized selectively, resulting in a low molecular weight to prevent generation and hence adhesion of a polymer.

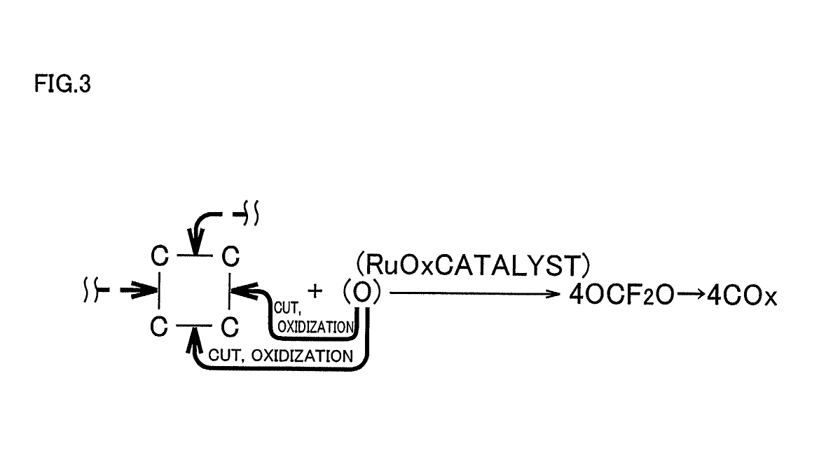

Furthermore, using an oxidization catalyst of RuOₓ and an etching gas of C₄F₈ (octafluorocyclobutane) having a cyclic bond of the fluorocarbon type gas and O₂ and Ar gas in the form of a gaseous mixture, prevents production of a polymer. More specifically, in the presence of the oxidization catalyst RuOₓ the cyclic bond of C₄F₈ is destroyed by an oxygen atom, as shown in FIG. 3, resulting in a low molecular weight.

Other than gaseous oxygen O₂, the gas capable of supplying an oxygen atom can be O₃, CO, CO₂, N₂O, H₂O, H₂O₂. Furthermore, an oxide of osmium (Os), iron (Fe) or the like readily oxidizes an organic compound and the oxide is a type of oxidization catalyst as it has a property of being reduced.

Thus when a metal of an oxidization catalyst is contained in a component, the component can have a surface with an oxidization reaction occurring to cleave an unsaturated bond to prevent production of a polymer and hence particles and other similar dust.

Third Embodiment

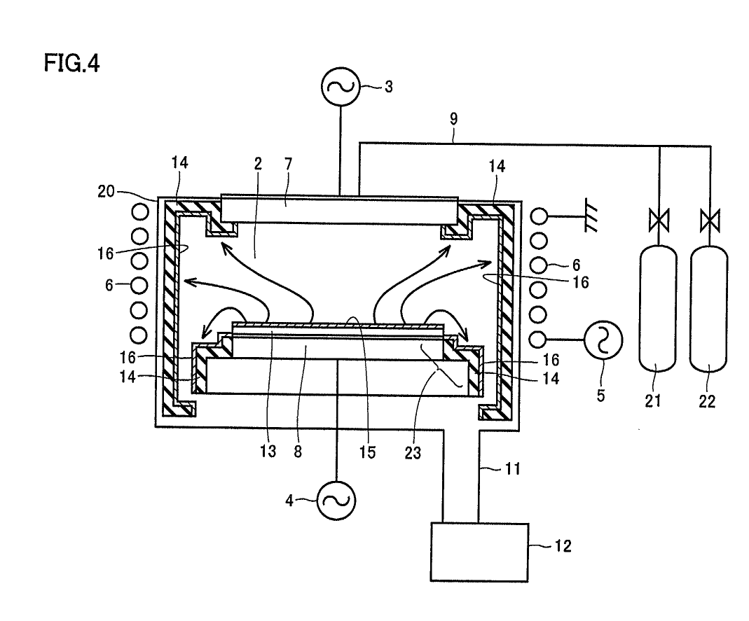

FIG. 4 shows a configuration of a plasma etching apparatus of a third embodiment of the present invention. In the first and second embodiments, the reaction chamber has an internal surface with a catalyst arranged to reduce the polymerization reaction as described above, or coated with a catalyst. In the present embodiment, the reaction chamber has a substance arranged therein to reduce the above polymerization reaction, as will now be described specifically.

The anti-polymerization reaction substance can be arranged (a) after wet-cleaning the reaction chamber (b) in a predetermined temporal cycle, or (c) before processing the product. The present embodiment uses a wafer with a catalyst metal spattered and thus deposited thereon. As such, for wafer 15 any semiconductor device is not formed and the wafer is dedicated to processing an internal surface of the reaction chamber. The wafer with the catalyst metal deposited thereon is input to the reaction chamber and processed with plasma (or etched) and the catalyst transpired is allowed to adhere to a surface of deposition shield cover 14 covering internal surface 20 of the reaction chamber and substrate support 23.

For example, a wafer having a surface with Pt or Ru exposed, or a wafer with Pt or Ru exposed when a surface thereof is etched by a predetermined thickness, is etched in a plasma. This allows the reaction chamber to have an internal surface coated with a thin film of Pt or Ru 16 and thus having arranged thereon thin film 16 of the catalyst for hydrogenation or oxidization catalyst referred to in the first or second embodiment. As such, if with a semiconductor device being fabricated an insulation film of a wafer is etched with the flourocarbon type gas, fluorocarbon polymer can be prevented from adhering to a surface of the reaction chamber thick and producing particles or other similar dust. This method does not require arranging any particular component in the reaction chamber and it only requires to prepare a wafer dedicated to processing an internal surface of the reaction chamber, as described above, and process the wafer with plasma. This can readily prevent particles attributed to using the fluorocarbon type gas in a conventional plasma etching apparatus.

Fourth Embodiment

FIG. 4 shows a configuration of a plasma etching apparatus of a fourth embodiment of the present invention. If the fluorocarbon type gas is used as an etching gas, polymer film can deposit in a piping of a pump or in the exact pump and the piping may clog or the pump may break.

In the present embodiment, the piping of the pump or components in the pump are coated with a coating member 19 containing a catalyst reducing polymerization of the fluorocarbon type gas as has been described in the previous embodiments. This catalyst, as has been described previously, reduces polymerization of fluorocarbon and thus prevents production of a polymer and hence adhesion thereof to the piping of the pump and an internal surface of the pump member. Consequently, in addition to the above-described effect in the reaction chamber, the piping of the pump and the interior of the pump can be prevented from clogging otherwise attributed to adhesion of polymer film thereto and their maintainability can thus be enhanced.

Fifth Embodiment

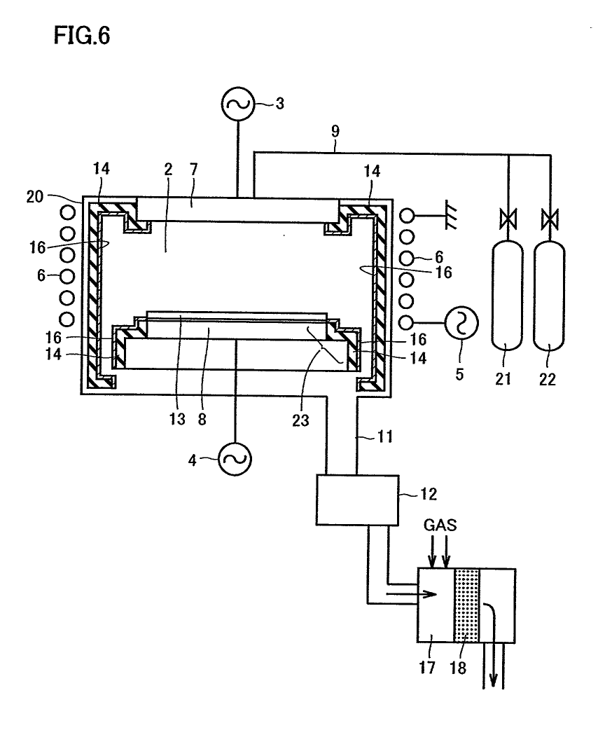

FIG. 6 shows a configuration of a plasma etching apparatus of a fifth embodiment of the present invention. If the fluorocarbon type gas is used as an etching gas, a hazardous-perfluorocarbon (PFC) eliminating device 17 is required on the exhaust system side. The hazardous-PFC eliminating device converts fluorocarbon to a lower molecular substance whether decomposition is provided by means of combustion, plasma, or catalyst. As such, effectively, the catalyst referred to in the first and second embodiments is arranged internal to reaction tower 18 of device 17 and the fluorocarbon type gas is oxidized or hydrogenated to provide a fluorocarbon molecule of a low molecular weight.

For example, if a gas capable of supplying hydrogen or oxygen is mixed with the fluorocarbon type gas and a Pt/Rh catalyst exists, a reaction is promoted, as follows:

(reaction in the presence of Pt/Rh): CxFy+(H)+(O)→mCOx+HF (water soluble)

The gas capable of supplying hydrogen and oxygen can be H₂O, H₂O₂, CH₃OH (alcohols).

Using the above catalyst for the hazard eliminating device can decompose and render flourocarbon gas innocuous at a lower temperature, more readily, at a lower cost and with a lower power than conventional.

The embodiments of the present invention have been described hereinabove, although the embodiments of the present invention disclosed as above are merely illustrative and they are not intended to limit the range of the present invention. For example, as described in the following items:

(1) the present invention is not limited to a plasma etching apparatus and it is applicable to a parallel plate RIE apparatus, an ECR apparatus, a downstream plasma reaction apparatus and the like;

(2) even if a catalyst for hydrogenation or an oxidization catalyst is used, it is not necessary to intentionally introduce a gas supplying a hydrogen atom involved in the H terminal formation reaction or a gas supplying an oxygen atom involved in oxidization reaction. It is preferable that a gas supplying hydrogen or oxygen atoms be introduced, although in some case, it is contained in an object to be etched of a semiconductor device or a hydrogen storing metal stores hydrogen therein. In such a case it is unnecessary to introduce the gas;

(3) the object to be etched is not limited to silicon oxide film, silicon nitride film or other similar insulation film. The present invention is applicable to etching a thin film for example of polysilicon, although it is not used to etch a type of metal film, such as aluminum film;

(4) the oxidization catalyst, the catalyst for hydrogenation and the hydrogen storing/discharging substance are not limited to the substances disclosed herein and any having the function required for them may be used; and

(5) the deposition shield cover covering an internal surface of the reaction chamber may be dispensed with, although if it is provided it can be exchanged periodically to reduce the probability of production of particles. If the deposition shield cover is not provided, a substance preventing a polymerization reaction of a fluorocarbon type molecule is arranged directly on the internal wall of the reaction chamber.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device fabrication apparatus using a fluorocarbon type gas as an etching gas to etch a thin film of a semiconductor device, comprising:
etching gas introduction means introducing an etching gas into a reaction chamber;
a reaction chamber in which a thin film of said semiconductor device is etched; and
exhaust means exhausting a gas from said reaction chamber,
a substance preventing a polymerization reaction of a molecule of said fluorocarbon type gas being provided internal to said reaction chamber to cover a surface of a portion of said reaction chamber contacting said etching gas.

2. The apparatus of claim 1, wherein said reaction chamber has an internal surface covered with a deposition shield cover and said substance preventing said polymerization reaction covers a surface of said deposition shield cover.

3. The apparatus of claim 1, wherein said substance preventing said polymerization reaction covers a surface of a substrate support supporting a substrate of said semiconductor device.

4. The apparatus of claim 1, wherein said substance preventing said polymerization reaction further covers an internal surface of a piping of a pump of said exhaust means.

5. The apparatus of claim 1, wherein said substance preventing said polymerization reaction further covers a surface of a gas passageway of a reaction tower internal to a hazard eliminating device internal to said exhaust means.

6. The apparatus of claim 1, a substrate containing said substance preventing said polymerization reaction is arranged in said reaction chamber and etched to adhere said substance to an internal surface of said reaction chamber.

7. The apparatus of claim 1, wherein said substance preventing said polymerization reaction is a catalyst for hydrogenation.

8. The apparatus of claim 7, wherein said catalyst for hydrogenation is formed of at least one of palladium (Pd), platinum (Pt), platinum/platinum oxide (Pt/PtO) and rhenium sulfide (ReS₂).

9. The apparatus of claim 1, wherein said substance preventing said polymerization reaction is an oxidization catalyst.

10. The apparatus of claim 9, wherein said oxidization catalyst is formed of at least one of platinum/rhodium (Pt/Rh), vanadium pentoxide (V₂O₅), copper/vanadium (Cu/V), ruthenium oxide (RuOₓ) and osmium oxide (OsO_{y}).

11. The apparatus of claim 1, wherein said substance preventing said polymerization reaction is a hydrogen storing or discharging substance.

12. The apparatus of claim 11, wherein said hydrogen storing or discharging metal is formed of at least one of platinum (Pt) and palladium (Pd).

13. The apparatus of claim 1, wherein said fluorocarbon type gas contains at least one of alkene (olefin) type gas, alkyne type gas, cycloalkane (cycloparaffin) type gas, cycloalkene (cylcoolefin) type gas and benzene derivative fluoride compound gas.

14. The apparatus of claim 1, in a form of a plasma etching apparatus.

15. A method using a fluorocarbon type gas as an etching gas to etch a thin film of a semiconductor device placed in a reaction chamber of an etching apparatus, comprising the steps of:
etching in said reaction chamber a substrate having arranged therewith a substance preventing a polymerization reaction of a molecule of said fluorocarbon type gas; and
introducing at least said fluorocarbon type gas into said reaction chamber and using said fluorocarbon type gas to etch a thin film of said semiconductor device.

16. The method of claim 15, wherein together with said fluorocarbon type gas, a gas supplying a hydrogen atom or an oxygen atom contributing to at least one of a reaction allowing a fluorocarbon type molecule to have a lower molecule weight, an H termination reaction and an oxidization reaction, is introduced into said reaction chamber to etch said thin film of said semiconductor device.

17. A method using the apparatus as recited in claim 1, to etch a thin film of a semiconductor device, comprising the steps of:
setting in a reaction chamber of the apparatus a semiconductor substrate having a thin film formed thereon; and
using at least a fluorocarbon type gas as an etching gas to etch said thin film of said semiconductor substrate placed in said reaction chamber.
